(19) United States
(12) Patent Application Publication
(10) Pub. No.: US 2025/0385230 A1
(43) Pub. Date: Dec. 18, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chun-Chong CHIEN, Taichung City (TW); Hsin-Lung CHEN, Taichung City (TW); Chih-Hsien CHIU, Taichung City (TW); Wen-Jung TSAI, Taichung City (TW); Chun-Sheng CHANG, Taichung City (TW)

(21) Appl. No.: 19/004,837

(22) Filed: Dec. 30, 2024

(30) Foreign Application Priority Data
Jun. 17, 2024 (TW) 113122372

(51) Int. Cl. H01L 25/16; H01L 23/31; H01L 23/538; H01L 23/552; H01Q 1/22

(52) U.S. Cl. CPC H01L 25/162; H01L 23/3107; H01L 23/5385; H01L 23/552; H01Q 1/2283

(57) ABSTRACT

An electronic package and a manufacturing method thereof are provided. The electronic package includes: a package module having a first side, a second side opposite to the first side and a first electronic element disposed on the first side; an antenna module having a first surface, a second surface opposite to the first surface; a second electronic element disposed between the second side of the package module and the first surface of the antenna module, in which the first surface of the antenna module is disposed on the second side of the package module via a plurality of conductive elements; and a covering layer covering the second electronic element, in which the second electronic element and the covering layer are thinned to reduce thickness of the electronic package.

### CROSS-REFERENCE TO RELATED APPLICATIONS

The present application is based upon and claims the right of priority to TW Patent Application No. 113122372, filed Jun. 17, 2024, the disclosure of which is hereby incorporated by reference herein in its entirety for all purposes

### BACKGROUND

### 1. Technical Field

The present disclosure relates to a semiconductor packaging process, and more particularly, to an electronic package with an antenna structure and manufacturing method thereof.

### 2. Description of Related Art

Recently, wireless communication technology has been widely applied in various consumer electronic products (such as cell phones, tablet computers, etc.) to facilitate to receive or send various wireless signals. At the same time, in order to satisfy the portability and internet convenience of consumer electronic products, the manufacturing and design of wireless communication modules are developed towards the requirements of being light, thin, short and small, in which the patch antenna has been widely used in wireless communication modules of electronic products due to its characteristics such as small volume, light weight and easy manufacturing.

FIG. 1 is a schematic cross-sectional view of a conventional semiconductor package 1 integrated with an antenna. The semiconductor package 1 includes a package module 1a and an antenna module 1b, the package module 1a has a substrate 10, a radio frequency chip 11, and a power amplifier chip 12, the substrate 10 has a first side 10a and a second side 10b opposite to the first side 10a, the radio frequency chip 11 and the power amplifier chip 12 are disposed on the first side 10a of the substrate 10, the antenna module 1b is disposed on the second side 10b of the substrate 10 via a plurality of conductive elements 13.

In the conventional semiconductor package 1, in order to cope with the rapid decay of the radio frequency signal, the radio frequency chip 11 and the power amplifier chip 12 must be disposed on the first side 10a of the substrate 10 at the same time to enhance the signal strength. However, such design leads to an increase in the layout area of the substrate 10, the volume of the semiconductor package 1 is thus increased, thereby it is difficult for the semiconductor package 1 to meet the requirements of being light, thin, short and small.

In addition, the aforementioned semiconductor package 1 needs to be designed with conductive elements 13 with sufficient dimension to support the substrate 10 and the radio frequency chip 11 and the power amplifier chip 12 thereon. However, under the same area, conductive elements 13 with larger dimension will cause the spacing between each other to be reduced. In order to increase the number of conductive elements 13 required in the original design, the dimension of the package module 1a must be increased (and the antenna module 1b must also be enlarged at the same time), and therefore, it is not feasible to meet the requirements of being light, thin, short and small for end products.

Therefore, there is an urgent to overcome the aforementioned problems of conventional techniques.

### SUMMARY

In view of the aforementioned shortcomings of the prior art, the present disclosure provides an electronic package including: a package module has a first side and a second side opposite to the first side, a first electronic element and a plurality of conductive bumps, in which the first electronic element is disposed on the first side, and the plurality of conductive bumps are disposed on the second side; an antenna module has a first surface, a second surface opposite to the first surface, and a plurality of conductive elements disposed on the first surface for electrically connecting the antenna module to the plurality of conductive bumps of the package module via the plurality of conductive elements; a second electronic element disposed on the second side of the package module or the first surface of the antenna module, in order for the second electronic element and the plurality of conductive bumps or the plurality of conductive elements to be disposed on a same side; and a covering layer covering the second electronic element and the plurality of conductive bumps or the plurality of conductive elements which are disposed on the same side with the second electronic element.

The present disclosure further provides a manufacturing method of an electronic package, including: providing a package module and an antenna module, in which the package module has a first side and a second side opposite to the first side, a first electronic element is disposed on the first side, a plurality of conductive bumps are disposed on the second side, and the antenna module has a first surface, a second surface opposite to the first surface, and a plurality of conductive elements disposed on the first surface thereof; disposing a second electronic element on the second side of the package module or the first surface of the antenna module, in a manner that the second electronic element and the plurality of conductive bumps or the plurality of conductive elements are disposed on a same side; covering the second electronic element and the plurality of conductive bumps or the plurality of conductive elements which are disposed on the same side with the second electronic element by a covering layer; and electrically connecting the antenna module to the plurality of conductive bumps of the package module via the plurality of conductive elements.

In the aforementioned electronic package and the manufacturing method thereof, the covering layer and the second electronic element are thinned and disposed between the package module and the antenna module.

In the aforementioned electronic package and the manufacturing method thereof, the first electronic element is a radio frequency chip, and the second electronic element is a power amplifier chip.

In the aforementioned electronic package and the manufacturing method thereof, the second electronic element is disposed on the first surface of the antenna module in a flip-chip manner, or disposed on the second side of the package module in the flip-chip manner.

In the aforementioned electronic package and the manufacturing method thereof, the package module further includes a connecting element disposed on the first side thereof.

In the aforementioned electronic package and the manufacturing method thereof, an underfill is further formed between the package module and the antenna module to encapsulate the plurality of conductive bumps or the plurality of conductive elements that are not covered by the covering layer.

In the aforementioned electronic package and the manufacturing method thereof, a surface of the second electronic element is partially exposed from the covering layer.

In the aforementioned electronic package and the manufacturing method thereof, the second electronic element is not exposed from the covering layer.

In the aforementioned electronic package and the manufacturing method thereof, a plurality of the antenna modules are provided for electrically connecting the package module to the plurality of conductive elements of the plurality of antenna modules via the plurality of conductive bumps.

In the aforementioned electronic package and the manufacturing method thereof, the antenna module includes a plurality of antenna structures arranged on the second surface thereof.

In the aforementioned electronic package and the manufacturing method thereof, which further includes a cladding layer disposed on the antenna module to cover the plurality of antenna structures.

It can be seen from the above that, the electronic package and the manufacturing method thereof of the present disclosure mainly dispose the second electronic element between the package module and the antenna module, which in combination with the conductive bumps (or conductive elements) are all covered by the covering layer and thinned. Therefore, not only is a number of conductive connections on the side of the antenna module maintained, but also a dimension of the overall electronic package can be reduced.

### BRIEF DESCRIPTION OF THE DRAWINGS

FIG. 1 is a schematic cross-sectional view showing a conventional semiconductor package.

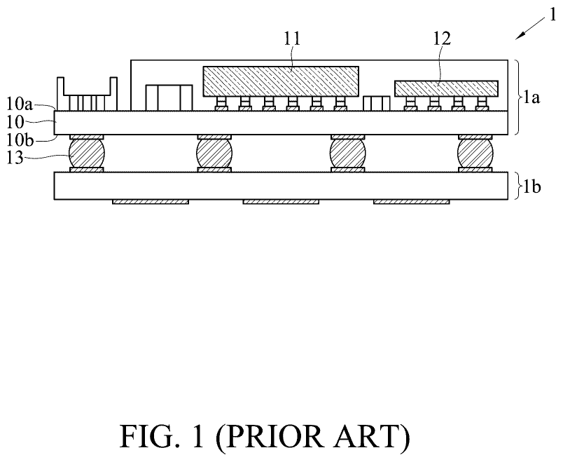

FIG. 2A to FIG. 2C are schematic cross-sectional views showing the manufacturing method of the electronic package of the present disclosure.

FIG. 3 is a schematic cross-sectional view showing a second embodiment of the electronic package of the present disclosure.

FIG. 4A and FIG. 4B are schematic cross-sectional views showing a third embodiment of the electronic package of the present disclosure.

FIG. 5A and FIG. 5B are schematic cross-sectional views showing a fourth embodiment of the electronic package of the present disclosure.

FIG. 6A and FIG. 6B are schematic cross-sectional views showing a fifth embodiment of the electronic package of the present disclosure.

FIG. 7A and FIG. 7B are schematic cross-sectional views showing a sixth embodiment of the electronic package of the present disclosure.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” and the like are merely used for clear explanation rather than limiting the practicable scope of the present disclosure, and thus, alterations or adjustments of the relative relationships thereof without essentially altering the technical contents should still be considered in the practicable scope of the present disclosure.

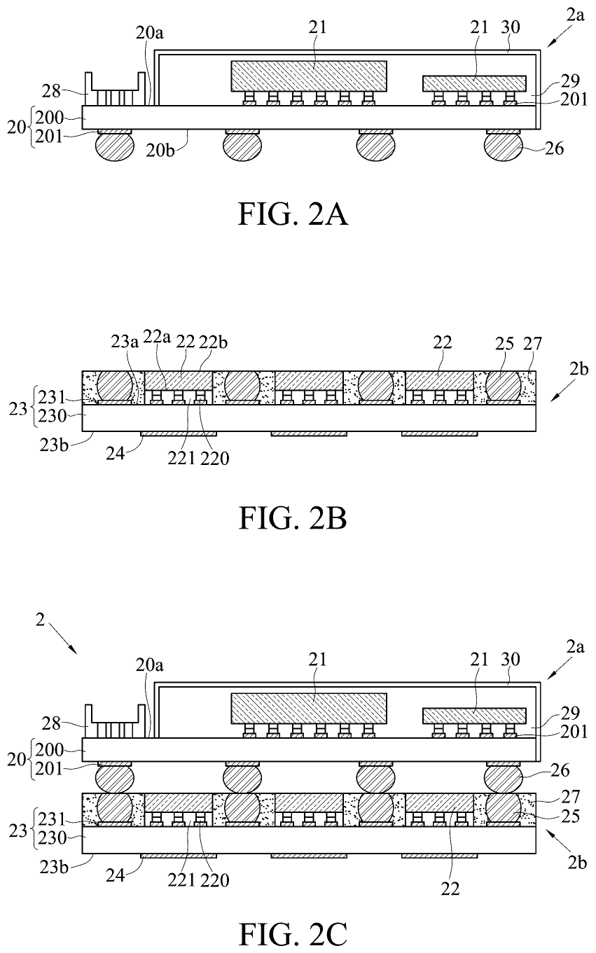

FIG. 2A to FIG. 2C are schematic cross-sectional views showing the manufacturing method of the electronic package 2 of the present disclosure.

As shown in FIG. 2A, a package module 2a that is a system in package (SiP) structure is provided, including a substrate 20, a first electronic element 21 and a connecting element 28 disposed on the substrate 20, and an encapsulation layer 29 disposed on the substrate 20 and covered the first electronic element 21.

The substrate 20 has a first side 20a and a second side 20b opposite to the first side 20a, for example, a substrate with a core layer or a coreless carrier, which forms a plurality of wiring layers 201 such as redistribution layer (RDL) on a dielectric material 200.

The first electronic element 21 is disposed on the first side 20a of the substrate 20 and electrically connected to the wiring layers 201. The first electronic element 21 can be, for example, an active element, a passive element, or a combination thereof. The active element is, for example, a semiconductor chip, the passive element is, for example, a resistor, a capacitor, and a capacitor.

In an embodiment, the first electronic element 21 is a semiconductor chip, specifically a radio frequency chip (RFIC), and is disposed on the first side 20a of the substrate 20. In other embodiments, the first electronic element 21 can also be electrically connected to the wiring layers 201 through wiring, a direct contact, or other appropriate means.

The connecting element 28 is disposed on the first side 20a of the substrate 20, and the encapsulation layer 29 is exposed from the connecting element 28. The connecting element 28 is spaced apart from the first electronic element 21. The connecting element 28 can be specifically a connector.

The encapsulation layer 29 is disposed on the first side 20a of the substrate 20 and covers the first electronic element 21. In an embodiment, the encapsulation layer 29 can be an insulating material, such as polyimide (PI), dry film, epoxy encapsulating colloid or molding compound, but not limited to the above.

Besides, a plurality of conductive bumps such as solder balls are disposed on the wiring layers 201 on the second side 20b of the substrate 20.

In an embodiment, a shielding structure 30 can be formed on the encapsulation layer 29 according to requirement to cover the first electronic element 21, such that the first electronic element 21 is prevented from external electromagnetic interference. Further, a layout area of the shielding structure 30 can be extended to a side surface of the substrate 20 according to requirement.

As shown in FIG. 2B, an antenna module 2b is disposed, a plurality of conductive elements 25 and a plurality of second electronic elements 22 are disposed on the antenna module 2b, and a covering layer 27 covering the plurality of second electronic elements 22 and the plurality of conductive elements 25 is formed.

The antenna module 2b includes a broad body 23 and a plurality of antenna structures 24. The broad body 23 is a base material of an antenna substrate and has a first surface 23a and a second surface 23b opposite to the first surface 23a. The broad body 23 has a dielectric material 230 and a wiring layer 231, such that the broad body 23 can be a substrate with a core layer and a circuit structure, or a coreless circuit structure form, but not be limited to the above. The plurality of antenna structures 24 are, for example, arranged in an array on the second surface 23b of the broad body 23. For example, the plurality of antenna structures 24 may include a patch antenna layer with multi-layer coupling, and may be single-frequency antenna design or multi-band antenna design with more than two bandwidths, thereby the second surface 23b of the broad body 23 serves as an antenna signal transmitting and receiving surface.

In an embodiment, the material of the wiring layer 231 is copper, and the dielectric material 230 is, for example, polybenzoxazole (PBO), polyimide (PI), prepreg (PP), etc.

The plurality of conductive elements 25 are disposed on the first surface 23a of the broad body 23 and electrically connected to the wiring layer 231, for example, the plurality of conductive elements 25 can be spherical or columnar solder materials or copper materials, but not be limited to the above. In other embodiments, the conductive elements 25 can also be Cu core balls, but not be limited to the above.

The second electronic element 22 has an active surface 22a and a non-active surface 22b, and the active surface 22a is disposed on the first surface 23a of the antenna module 2b via a bump 220 and a underfill 221 to electrically connect the second electronic element 22 to the wiring layer 231. The second electronic element 22 is, for example, a semiconductor chip, specifically a power amplifier IC.

In an embodiment, the second electronic element 22 is disposed on the first surface 23a of the antenna module 2b in a flip-chip manner, bot not be limited to the above, which can also be electrically connected to the wiring layer 231 through other proper ways.

Besides, a covering layer 27 is formed on the first surface 23a of the broad body 23 to cover the second electronic elements 22 and the conductive elements 25 disposed on the same side, and can be formed through a thinning process such as grinding, thereby the non-active surface 22b of the second electronic element 22 and end surfaces of the conductive elements 25 are exposed from the covering layer 27. The covering layer 27 can be, for example, an insulating material such as polyimide (PI), dry film, epoxy encapsulating colloid, or molding compound, etc.

In an embodiment, manufacturing the package module 2a shown in FIG. 2A and the antenna module 2b shown in FIG. 2B has no sequence and can be manufactured simultaneously in different production lines or sequentially in the same production line.

As shown in FIG. 2C, the package module 2a is connected to the conductive elements 25 of the antenna module 2b via conductive bumps 26, thereby the second electronic element 22 is located between the package module 2a and the antenna module 2b. Therefore, the package module 2a and the antenna module 2b are electrically connected to each other to manufacture the electronic package 2 of the present disclosure.

Furthermore, if the conductive bumps 26 and the conductive elements 25 are made of the same of similar material, they may be fused into one piece after welding in a high temperature.

The present disclosure can perform a grinding process on the non-active surface 22b of the second electronic element 22 and the covering layer 27 to reduce thicknesses of the second electronic element 22 and the covering layer 27. Further, the present disclosure can use a small-sized conductive element 25 to increase the number of contacts, and thus a distance between the first surface 23a of the broad body 23 and the second side 20b of the substrate 20 is reduced, thereby an overall thickness of the electronic package 2 is thinned.

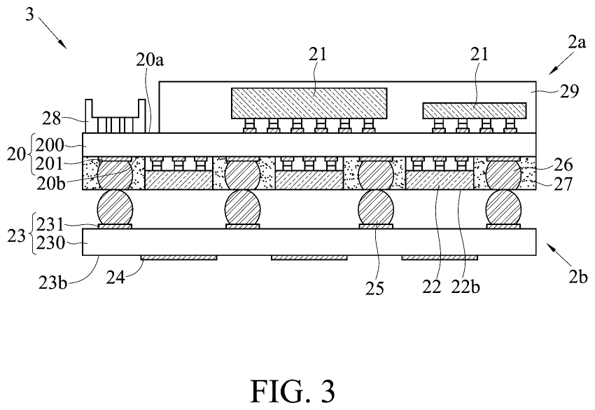

Please refer to FIG. 3, which is a schematic view showing the second embodiment of the electronic package 3 of the present disclosure. This embodiment is substantially the same as the previous embodiment. Compared to the first embodiment, the second electronic element 22 (a power amplifier chip) is disposed on the antenna module 2b and is on the same side as the conductive elements 25 to be closer to the antenna structures 24. In this embodiment, the second electronic element 22 is disposed on the second side 20b of the substrate 20 of the package module 2a and is electrically connected to the wiring layers 201, and therefore the second electronic element 22 (the power amplifier chip) is disposed on the same side as the conductive bumps 26 and is thus closer to the first electronic element 21 (a radio frequency chip). At the same time, the covering layer 27 is formed on the second side 20b of the substrate 20 to cover the second electronic element 22 and the conductive bumps 26, and through a thinning process such as grinding, the non-active surface 22b of the second electronic element 22 and end surfaces of the conductive bumps 26 are exposed from the covering layer 27. In addition, the plurality of conductive elements 25 are disposed on the antenna module 2b for the package module 2a to connect to the conductive elements 25 of the antenna module 2b through the conductive bumps 26.

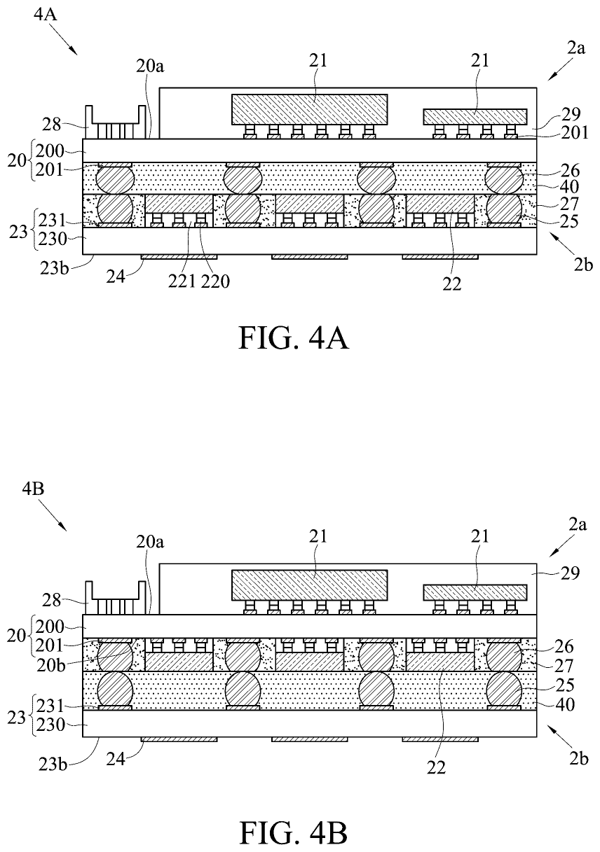

Please refer to FIG. 4A and FIG. 4B, which are schematic views showing the third embodiment of the electronic packages 4A, 4B of the present disclosure. This embodiment is substantially the same as the previous embodiment. The main difference is that after the package module 2a is connected to the conductive elements 25 of the antenna module 2b via the conductive bumps 26, an underfill 40 is filled between the package module 2a and the antenna module 2b, thereby the underfill 40 covers the conductive bumps 26 shown in FIG. 4A or covers the conductive elements 25 shown in FIG. 4B.

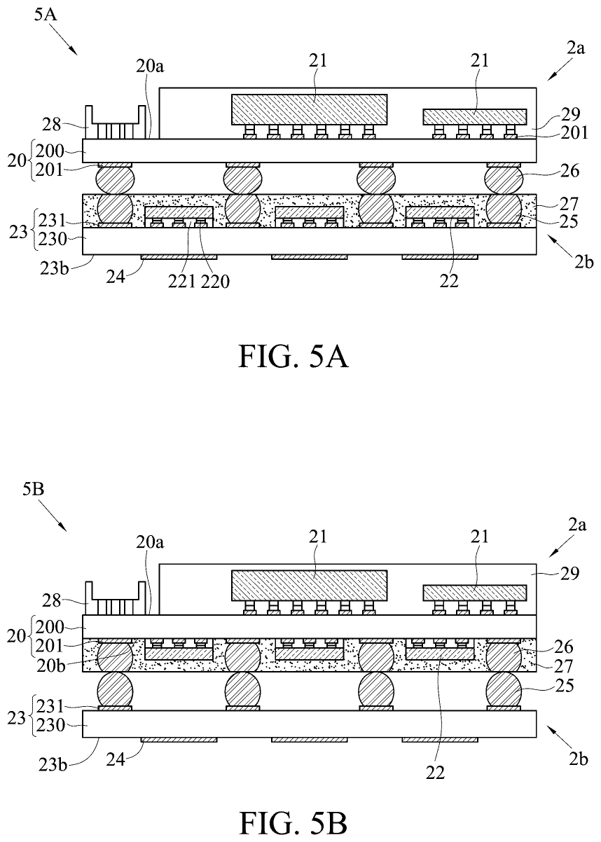

Please refer to FIG. 5A and FIG. 5B, which are schematic views showing the fourth embodiment of the electronic packages 5A, 5B of the present disclosure. This embodiment is substantially the same as the previous embodiment. The main difference is that the second electronic element 22 is not exposed from the covering layer 27, yet the end surfaces of the conductive elements 25 is exposed from the covering layer 27, and thus the conductive elements 25 is electrically connected to the conductive bumps 26.

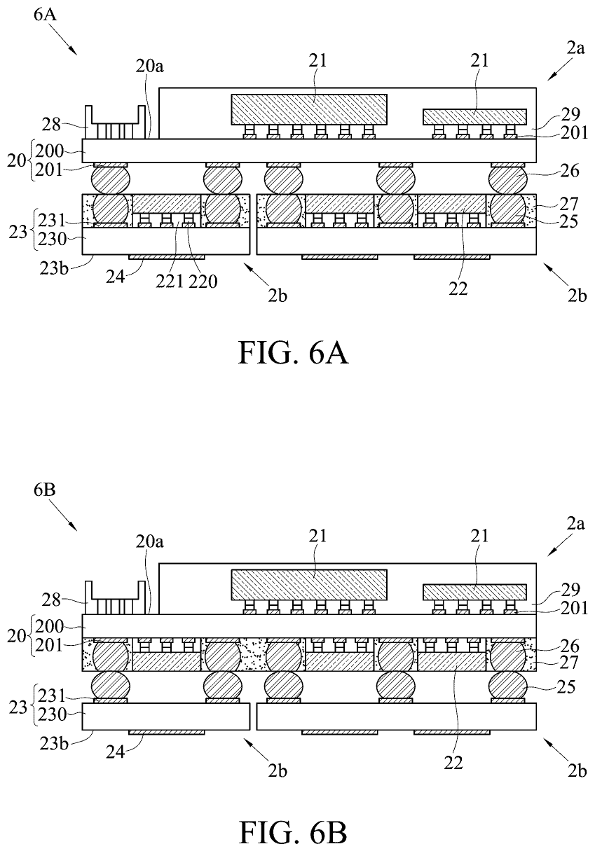

Please refer to FIG. 6A and FIG. 6B, which are schematic views showing the fifth embodiment of the electronic packages 6A, 6B of the present disclosure. This embodiment is substantially the same as the previous embodiment. The main difference is that this embodiment shows a plurality of antenna modules 2b for the package module 2a to electrically connect to the plurality of conductive elements 25 of the plurality of antenna modules 2b through the plurality of conductive bumps 26.

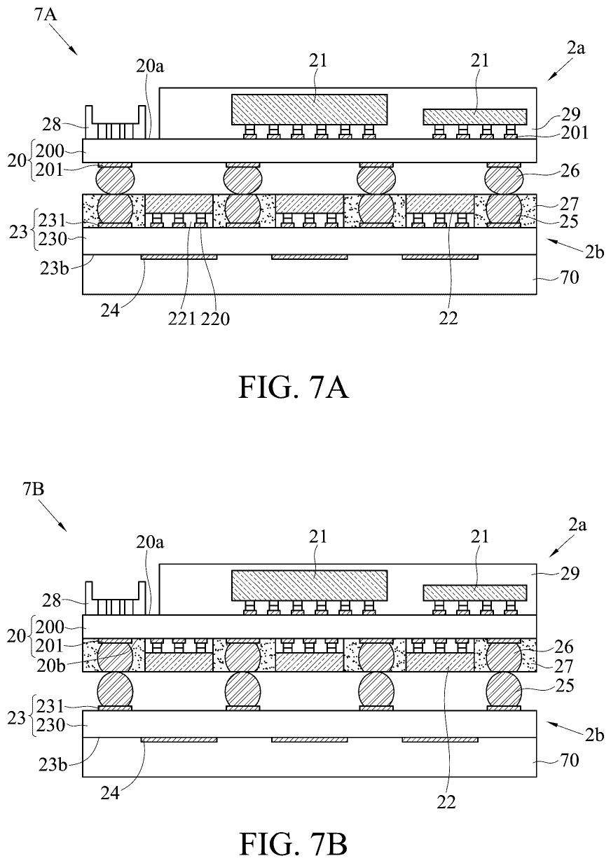

Please refer to FIG. 7A and FIG. 7B, which are schematic views showing the sixth embodiment of the electronic packages 7A, 7B of the present disclosure. This embodiment is substantially the same as the previous embodiment. The main difference is that a cladding layer 70 is formed on the antenna module 2b to cover the antenna structures 24, and the cladding layer 70 is, for example, an epoxy molding compounds (EMC) with a high dielectric constant (Dk>3.7).

To sum up, the electronic package and the manufacturing method thereof of the present disclosure mainly dispose the second electronic element (the power amplifier chip) between the antenna module and the package module. In addition to improving the signal performance, the layout area required for the package module can be effectively reduced, and therefore the overall volume of the electronic package can meet the requirements of being light, thin, short, and small.

In addition, since the second electronic element (the power amplifier chip) together with the conductive bumps (or conductive elements) are covered by the covering layer and thinned, not only can be the number of the conductive connections on the antenna module side maintained, but also the final electronic package can be thinner (since the power amplifier chip can be thinned). In specific, if the power amplifier chip is thinned at the beginning before connected to the antenna module (or the package module), the power amplifier chip is too thin for the mechanical suction nozzle to suck the power amplifier chip onto the antenna module (or the package module), and thus the power amplifier chip cannot be thinned at the beginning before a die placement operation is performed. Therefore, the present disclosure firstly places the power amplifier chip on the antenna module (or the package module), and the power amplifier chip is covered by the encapsulation layer. Accordingly, the power amplifier chip can be further thinned, and ultimately the dimension of the overall electronic package can be reduced.

Additionally, the aforementioned structure can solve the existing technical problems in the industry without adding development processes and materials or purchasing machines, and thus there will be no a large amount of additional costs.

The above embodiments are disposed for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a package module having a first side and a second side opposite to the first side, wherein a first electronic element is disposed on the first side, and a plurality of conductive bumps are disposed on the second side;
an antenna module having a first surface, a second surface opposite to the first surface, and a plurality of conductive elements disposed on the first surface for electrically connecting the antenna module to the plurality of conductive bumps of the package module via the plurality of conductive elements;
a second electronic element disposed on the second side of the package module or the first surface of the antenna module, in order for the second electronic element and the plurality of conductive bumps or the plurality of conductive elements to be disposed on a same side; and
a covering layer covering the second electronic element and the plurality of conductive bumps or the plurality of conductive elements which one disposed on the same side with the second electronic element.

2. The electronic package of claim 1, wherein the covering layer and the second electronic element are thinned and disposed between the package module and the antenna module.

3. The electronic package of claim 1, wherein the first electronic element is a radio frequency chip, and the second electronic element is a power amplifier chip.

4. The electronic package of claim 1, wherein the second electronic element is disposed on the first surface of the antenna module in a flip-chip manner, or disposed on the second side of the package module in the flip-chip manner.

5. The electronic package of claim 1, wherein the package module further comprises a connecting element disposed on the first side of the package module.

6. The electronic package of claim 1, further comprising an underfill filled between the package module and the antenna module to encapsulate the plurality of conductive bumps or the plurality of conductive elements that are not covered by the covering layer.

7. The electronic package of claim 1, wherein a surface of the second electronic element is partially exposed from the covering layer.

8. The electronic package of claim 1, wherein the second electronic element is not exposed from the covering layer.

9. The electronic package of claim 1, which comprises a plurality of the antenna modules for electrically connecting the package module to the plurality of conductive elements of the plurality of antenna modules via the plurality of conductive bumps.

10. The electronic package of claim 1, wherein the antenna module comprises a plurality of antenna structures arranged on the second surface thereof.

11. The electronic package of claim 10, further comprising a cladding layer disposed on the antenna module to cover the plurality of antenna structures.

12. A manufacturing method of an electronic package, comprising:
providing a package module and an antenna module, wherein the package module includes a first side and a second side opposite to the first side, a first electronic element is disposed on the first side, a plurality of conductive bumps are disposed on the second side, and the antenna module includes a first surface, a second surface opposite to the first surface, and a plurality of conductive elements disposed on the first surface thereof;
disposing a second electronic element on the second side of the package module or the first surface of the antenna module, in a manner that the second electronic element and the plurality of conductive bumps or the plurality of conductive elements are disposed on a same side;
covering the second electronic element and covering the plurality of conductive bumps or the plurality of conductive elements which are disposed on the same side with the second electronic element by a covering layer; and
electrically connecting the antenna module to the plurality of conductive bumps of the package module via the plurality of conductive elements.

13. The method of claim 12, wherein the covering layer and the second electronic element are thinned and disposed between the package module and the antenna module.

14. The method of claim 12, wherein the first electronic element is a radio frequency chip, and the second electronic element is a power amplifier chip.

15. The method of claim 12, wherein the second electronic element is disposed on the first surface of the antenna module in a flip-chip manner, or disposed on the second side of the package module in the flip-chip manner.

16. The method of claim 12, wherein the package module further comprises a connecting element disposed on the first side thereof.

17. The method of claim 12, further comprising an underfill formed between the package module and the antenna module to encapsulate the plurality of conductive bumps or the plurality of conductive elements that are not covered by the covering layer.

18. The method of claim 12, wherein a surface of the second electronic element is partially exposed from the covering layer.

19. The method of claim 12, wherein the second electronic element is not exposed from the covering layer.

20. The method of claim 12, further comprising a plurality of the antenna modules for electrically connecting the package module to the plurality of conductive elements of the plurality of antenna modules via the plurality of conductive bumps.

21. The method of claim 12, wherein the antenna module comprises a plurality of antenna structures arranged on the second surface thereof.

22. The method of claim 21, further comprising a cladding layer formed on the antenna module to cover the plurality of antenna structures.
